(19) United States
(12) Patent Application Publication
(10) Pub. No.: US 2026/0171367 A1
(43) Pub. Date: Jun. 18, 2026

(54) REACTOR SYSTEM

(71) Applicant: ASM IP Holding B.V., Almere (NL)

(72) Inventors: Satya Vamshi Pattela, Phoenix, AZ (US); Harihara Krishnan Krishnamoorthy, Tempe, AZ (US); Kyle Fondurulia, Phoenix, AZ (US); Ankit Kimtee, Phoenix, AZ (US)

(21) Appl. No.: 19/415,931

(22) Filed: Dec. 11, 2025

Related U.S. Application Data
(60) Provisional application No. 63/734,499, filed on Dec. 16, 2024.

(51) Int. Cl. H01J 37/32

(52) U.S. Cl. CPC H01J 37/3244; H01J 37/32357; H01J 37/32467; H01J 2237/332

(57) ABSTRACT

A reactor system can comprise a remote plasma unit, a reactor coupled to the remote plasma unit, and/or an activated species supply system. The reactor can comprise a reaction chamber, a diffuser in fluid communication with the reaction chamber, and/or a mixer coupled to, and in fluid communication with, the diffuser. The mixer can comprise a mixing chamber and a mixer fluid channel fluidly coupled to, and upstream of, the mixing chamber. The activated species supply system can comprise an activated species supply conduit that fluidly couples the remote plasma unit with the mixer.

### CROSS-REFERENCE TO RELATED APPLICATIONS

This application is a nonprovisional of, and claims priority to and the benefit of, U.S. Provisional Patent Application No. 63/734,499, filed Dec. 16, 2024 and entitled “REACTOR SYSTEM,” which is hereby incorporated by reference herein.

### FIELD

The present disclosure relates generally to reactor systems, and reactor systems including an activated species source.

### BACKGROUND

Reactors may be used for depositing various material layers onto substrates. A substrate can be placed on a substrate support structure inside a reaction chamber of a reactor. Both the substrate and the substrate support structure can be heated to a desired substrate temperature set point. In an example substrate deposition process, one or more reactant gases can be flowed to a mixer and/or diffuser to be provided to reaction chamber. The reactant gas(es) can be passed over a heated substrate, causing the deposition of a thin film of material on the substrate surface.

A reactor system can utilize an activate species (e.g., radicals and/or plasma) in deposition processing, etch processing, and/or the like. Accordingly, a reactor system can have components and/or a flow path to provide the activated species from a source (e.g., a remote plasma unit) to the reaction chamber.

### SUMMARY

This summary is provided to introduce a selection of concepts in a simplified form. These concepts are described in further detail in the detailed description of examples of the disclosure below. This summary is not intended to necessarily identify key features or essential features of the claimed subject matter, nor is it intended to be used to limit the scope of the claimed subject matter.

Examples described herein provide a reactor system comprising a remote plasma unit, a reactor coupled to the remote plasma unit, and/or an activated species supply system. The reactor can comprise a reaction chamber, a diffuser in fluid communication with the reaction chamber, and/or a mixer coupled to, and in fluid communication with, the diffuser. The mixer can comprise a mixing chamber and a mixer fluid channel fluidly coupled to, and upstream of, the mixing chamber. The mixer can comprise at least one of titanium metal or a titanium alloy. The activated species supply system can be fluidly coupled to the mixer upstream of the mixer fluid channel. The activated species supply system can comprise an activated species supply conduit that fluidly couples the remote plasma unit with the mixer. The reactor can further comprise a reactor lid, which can comprise a supply aperture.

The activated species supply system can further comprise a supply tube comprising a supply tube wall defining a supply tube channel and spanning between a supply tube proximal end and a supply tube distal end. The supply tube can comprise a steel alloy (e.g., stainless steel). The supply tube can be disposed through the supply aperture in the reactor lid. The activated species supply conduit can comprise the supply tube channel. The supply tube proximal end can be positioned against and/or coupled to the mixer such that the supply tube channel is in fluid communication with the mixer fluid channel. In various examples, the supply tube proximal end can comprise a coupling protrusion extending radially outward from the supply tube wall and configured to couple to the mixer. The coupling protrusion can be fastened to the mixer. The coupling protrusion can comprise a coupling flange with a flange shape. The mixer can comprise a coupling recess at an inlet of the mixer fluid channel. The coupling recess can comprise a shape that is complementary to the flange shape such that at least a portion of the coupling flange is disposed within the coupling recess. In various examples, the coupling protrusion can comprise a tapering surface that tapers radially inward toward the supply tube proximal end. The mixer can comprise a tapering coupling recess at an inlet of the mixer fluid channel. The tapering coupling recess can be complementary to the tapering surface of the coupling protrusion, such that at least a portion of the coupling protrusion is disposed within the tapering coupling recess. At least a partial seal can be formed between the supply tube proximal end and the mixer via tight fit.

The activated species supply system can further comprise a connector tube comprising a connector tube wall defining a connector tube channel and spanning between a connector tube proximal end and a connector tube distal end. The activated species supply conduit can comprise the connector tube channel. The connector tube can comprise a steel alloy (e.g., stainless steel). The connector tube distal end can be coupled to the supply tube distal end such that the supply tube channel is in fluid communication with the connector tube channel. The connector tube proximal end can be coupled to the remote plasma unit.

The activated species supply system can further comprise a connector flange coupled to the connector tube distal end. The connector flange can extend radially outward from the connector tube wall and can be coupled to the reactor lid. The connector flange can be a separate component coupled to the connector tube distal end or a monolithic component of the connector tube wall.

In various examples, the supply tube can comprise a supply tube flange protruding radially outward from the supply tube wall at a flange position between the supply tube proximal end and the supply tube distal end. The activated species supply system can further comprise a spring coupled to and/or disposed about the supply tube. The spring can have a spring first end applying force against the supply tube flange and a spring second end applying force against at least one of the connector flange, the reactor lid, or a reactor collar disposed between the connector flange and the reactor lid. In response to the connector flange or the reactor collar being coupled to the reactor lid, the spring can apply force on the supply tube flange causing greater contact between the supply tube proximal end and the mixer.

The reactor system can further comprise a gas source. The mixing chamber can further comprise a gas inlet, wherein the gas source is fluidly coupled to the mixing chamber via the gas inlet.

An inside surface of the mixer, the supply tube, and/or the connector tube can comprise a coating comprising aluminum oxide.

In various examples, a reactor system can comprise a mixer and/or a supply tube comprising a supply tube wall defining a supply tube channel and spanning between a supply tube proximal end and a supply tube distal end. The mixer can comprise a mixing chamber, a mixer fluid channel fluidly coupled to, and upstream of, the mixing chamber, and/or a mixer fluid channel inlet comprising a coupling recess. The supply tube proximal end can be disposed at least partially within the coupling recess of the mixer fluid channel inlet. The mixer can be a monolithic component including the mixing chamber and the mixer fluid channel. The mixer fluid channel can be an elbow joint between the supply tube and the mixing chamber. The supply tube proximal end can comprise a coupling protrusion extending radially outward from the supply tube wall. The coupling protrusion can comprise a shape that is complementary to a shape of the coupling recess.

In various examples, a reactor system can comprise a remote plasma unit, a reactor coupled to the remote plasma unit, the reactor comprising a mixer, and/or an activated species supply system fluidly coupled between the remote plasma unit and the mixer. The activated species supply system can comprise a supply tube coupled to the mixer. The activated species supply system can be disposed through a reactor lid. The activated species supply system can further comprise a spring coupled to and/or disposed about the supply tube and applying a force on the supply tube to cause greater contact between the supply tube and the mixer. The activated species supply system can further comprise a connector tube fluidly coupled between the supply tube and the remote plasma unit. The supply tube can span along a different axis than the connector tube.

For the purpose of summarizing the disclosure and the advantages achieved over the prior art, certain objects and advantages of the disclosure have been described herein. Of course, it is to be understood that not necessarily all such objects or advantages may be achieved in accordance with any particular example. Thus, for example, those skilled in the art will recognize that the disclosure may be embodied or carried out in a manner that achieves or optimizes one advantage or group of advantages as taught or suggested herein without necessarily achieving other objects or advantages as may be taught or suggested herein.

All of these examples are intended to be within the scope of the disclosure. These and other examples will become readily apparent to those skilled in the art from the following detailed description of certain examples having reference to the attached figures, the disclosure not being limited to any particular example(s).

### BRIEF DESCRIPTION OF THE DRAWINGS

While the specification concludes with claims particularly pointing out and distinctly claiming what are regarded as examples of the disclosure, the advantages of examples of the disclosure may be more readily ascertained from the description of certain examples of the disclosure when read in conjunction with the accompanying drawings. Elements with the like element numbering throughout the figures are intended to be the same.

FIG. 1A illustrates a reactor, in accordance with various examples.

FIG. 1B illustrates a cross-section of the reactor of FIG. 1A, in accordance with various examples.

FIG. 2A illustrates a reactor system, in accordance with various examples.

FIG. 2B illustrates a cross-section of a portion of the reactor system of FIG. 2A, in accordance with various examples.

FIG. 2C illustrates a cross-section of a portion of a reactor system, in accordance with various examples.

FIG. 2D illustrates a cross-section of a portion of a reactor system, in accordance with various examples.

FIG. 3 illustrates a cross-section of a supply tube, mixer, and diffuser of the reactor system of FIGS. 2A and 2B, in accordance with various examples.

FIG. 4 illustrates a cross-sectional perspective view of the mixer of FIGS. 2B and 3, in accordance with various examples.

FIG. 5 illustrates a cross-section of a supply tube, mixer, and diffuser of a reactor system, in accordance with various examples.

FIG. 6 illustrates a cross-sectional perspective view of the supply tube and mixer of FIG. 5, in accordance with various examples.

FIG. 7 illustrates a cross-sectional perspective view of a supply tube and mixer, in accordance with various examples.

It will be appreciated that elements in the figures are illustrated for simplicity and clarity and have not necessarily been drawn to scale. For example, the dimensions of some of the elements in the figures may be exaggerated relative to other elements to help improve understanding of illustrated examples of the present disclosure.

### DETAILED DESCRIPTION

The description of examples of methods, structures, devices, and systems provided below is merely exemplary and is intended for purposes of illustration only—the following description is not intended to limit the scope of the disclosure or the claims. Moreover, recitation of multiple examples having stated features is not intended to exclude other examples having additional features or other examples incorporating different combinations of the stated features. For example, various examples are set forth as embodiments and may be recited in the dependent claims. Unless otherwise noted, the examples or components thereof may be combined or may be applied separate from each other. Methods may include the disclosed steps in any suitable and/or desired order or combination.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the terms “includes,” “comprises,” “including,” and/or “comprising” specify the presence of stated features, integers, steps, processes, members, components, and/or groups thereof, but do not preclude the presence or addition of one or more other features, integers, steps, processes, members, components, and/or groups thereof. In this disclosure, any defined meanings do not necessarily exclude ordinary and customary meanings in some examples.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material.

In some examples, “film” refers to a layer extending in a direction perpendicular to a thickness direction. In some examples, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes. Cyclic deposition processes can include plasma-enhanced steps. A cyclic deposition process can include one or more cycles that include plasma activation of a precursor, a reactant, and/or an inert gas in any combination.

In this disclosure, any two numbers of a variable can constitute a workable range of the variable, any ranges indicated may include or exclude the endpoints, and all ranges and ratio limits disclosed herein may be combined. Additionally, any values of variables indicated (regardless of whether they are indicated with “about” or not) may refer to precise values or approximate values and include equivalents, and may refer to average, median, representative, majority, etc. in some examples. Unless specifically stated otherwise, references to “a,” “an,” and/or “the” may include one or more than one, and references to an item in the singular may also include the item in the plural. When referring to components of systems discussed herein, the term “coupled” refers to direct coupling or indirect coupling with other intervening elements, as appropriate. Unless otherwise indicated, the terms “first,” “second,” etc., and/or “primary,” “secondary,” etc., are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item. Further, reference to, e.g., a “first” item and a “second” item does not mean that there are no intervening items, and such intervening items may be present.

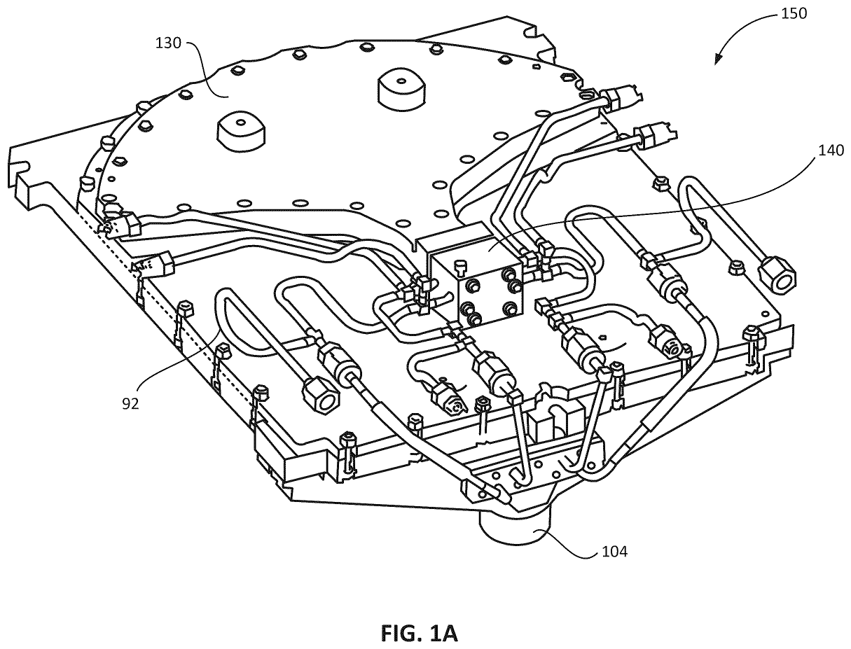

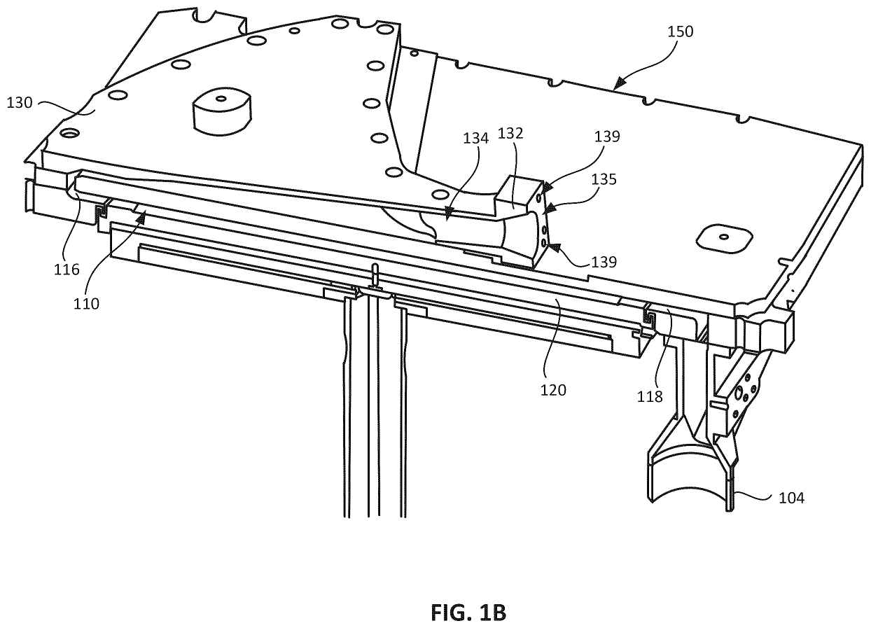

FIGS. 1A and 1B illustrate a gas-phase reactor system in accordance with various examples. The reactor system can include a reactor 150, including a reaction chamber 110, a susceptor 120, a diffuser 130, a mixer 140, and a reaction chamber exhaust conduit 104. Diffuser 130 can comprise a diffuser space 134 through which fluid can flow. Diffuser 130 can comprise a diffuser inlet 132, including a diffuser inlet surface 135. Diffuser inlet surface 135 can comprise one or more coupling apertures 139 disposed therein configured to receive a fastener (e.g., a screw, bolt, nail, and/or the like) to couple another component of reactor system 100 thereto (e.g., mixer 140). Reaction chamber 110 can comprise an inlet 116 fluidly coupling reaction chamber 110 to diffuser space 134, and an outlet 118 fluidly coupling reaction chamber 110 to exhaust conduit 104. System 100 may additionally include various gas sources (e.g., gas source 92), such as purge and reactant gas sources, and/or one or more exhaust and/or vacuum sources.

Reactor 150 may be used to deposit material onto a surface of a substrate, etch material from a surface of substrate, clean a surface of substrate, treat a surface of substrate, deposit material onto a surface within reaction chamber, clean a surface within reaction chamber, etch a surface within reaction chamber, and/or treat a surface within reaction chamber 110. Reactor 150 can be a standalone reactor or part of a cluster tool. Further, reactor 150 can be dedicated to deposition, etch, clean, or treatment processes, or reactor 150 may be used for multiple processes—e.g., for any combination of deposition, etch, clean, and treatment processes. By way of examples, reactor 150 may include a reactor typically used for chemical vapor deposition (CVD) processes, such as atomic layer deposition (ALD) processes.

Reaction chamber 110 can be a cross-flow reaction chamber. During operation, gases enter reaction chamber 110 via diffuser 130 and flow horizontally through reaction chamber 110 to exhaust conduit 104.

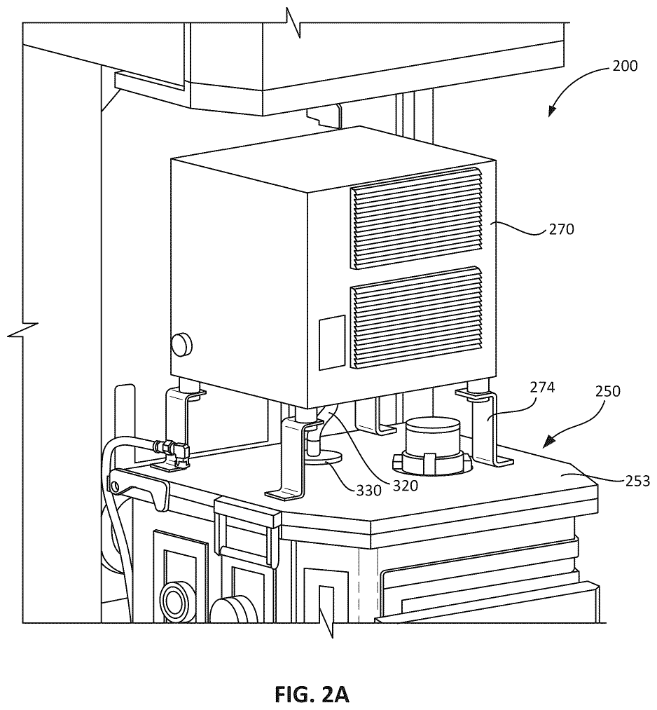

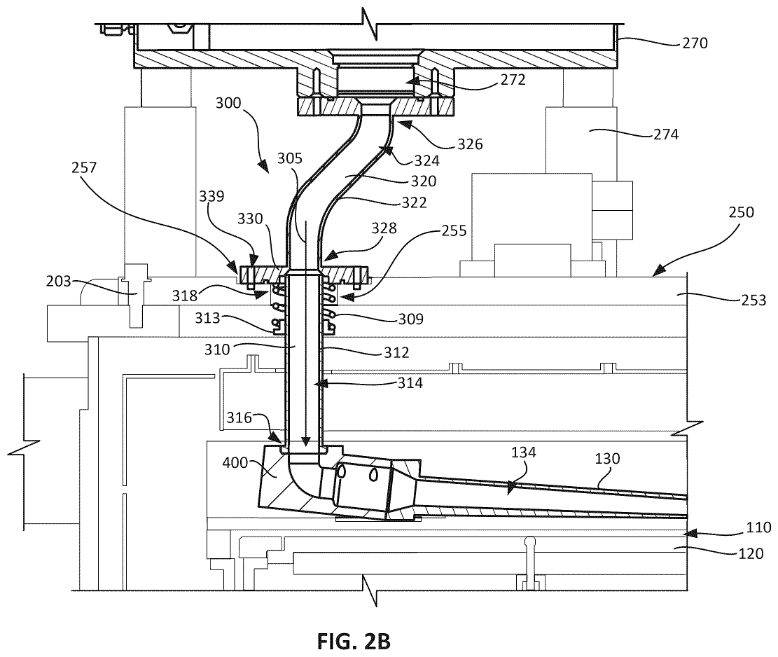

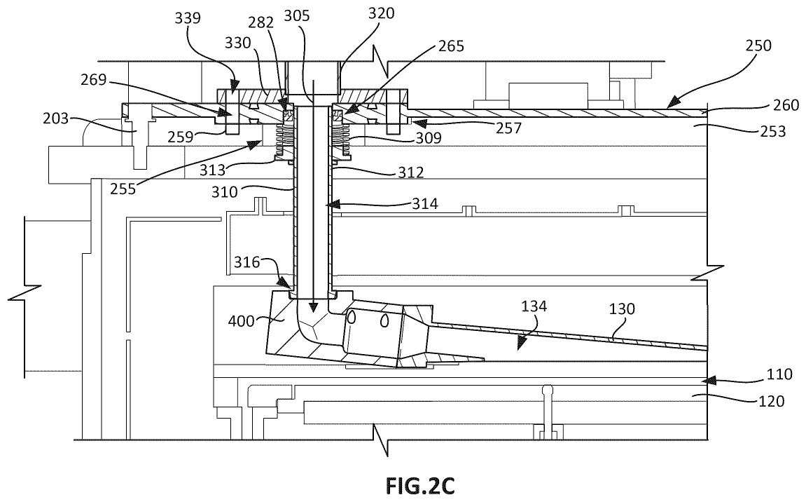

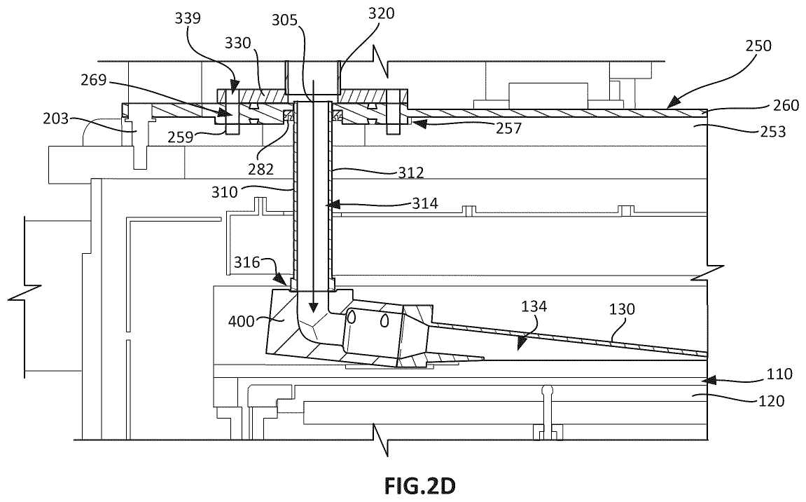

With reference to FIGS. 2A and 2B, a reactor system 200 is depicted comprising a reactor 250 and a remote plasma unit (RPU) 270 coupled to reactor 250. RPU 270 can be disposed in any suitable position relative to reactor 250, such as above or on top of reactor 250. RPU 270 can be supported and/or spaced apart from reactor 250, for example, via support legs 274. RPU 270 can produce an excited or activated species (e.g., ions, radicals, and/or the like), which can be flowed to reactor 250 for processing a substrate (e.g., film deposition or etch). RPU 270 can comprise an outlet 272, through which the activated species flows out of RPU 270 toward reactor 250.

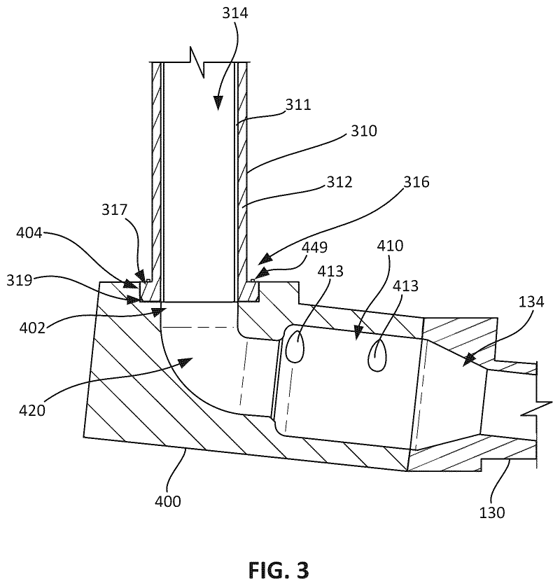

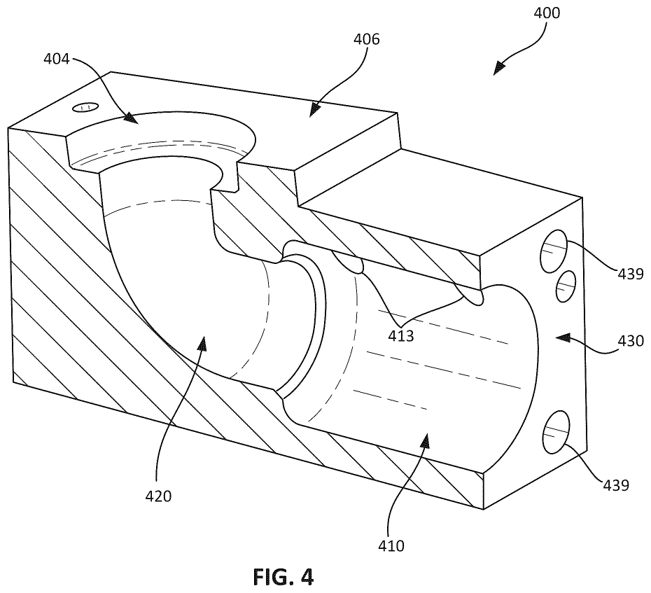

Reactor 250 can comprise a mixer 400 (similar to mixer 140 in FIGS. 1A and 1B). Mixer 400 can be configured to receive one or more fluids (e.g., gases) therein and/or facilitate combining or mixing of such fluids. Gases can then flow to diffuser 130 and into reaction chamber 110. With addition reference to FIGS. 3 and 4, a mixer 400 can comprise a mixing chamber 410 and a mixer fluid channel 420. Mixer fluid channel 420 can be fluidly coupled to, and upstream of, mixing chamber 410. Activated species can flow from RPU 270 into mixer 400 through mixer inlet 402 (which can be an inlet to mixer fluid channel 420). Mixer fluid channel 420 can comprise any suitable shape. For example, mixer fluid channel 420 can be shaped to change the direction of activated species flow from RPU 270 to mixing chamber 410. Mixer fluid channel 420 can be L-shaped (an elbow joint), receiving an activated species from above (i.e., the activated species flowing substantially in the direction of gravity from RPU 270) and directing the activated species in a lateral direction to mixing chamber 410.

Mixer 400 can comprise one or more gas inlets 413 disposed through the wall of mixing chamber 410. Gas inlets 413 can fluidly couple to a gas source (e.g., gas source 92), which can provide a reactant gas, precursor gas, etchant gas, carrier gas, purge gas, or any other desired gas, to mixer 400. Gas inlets 413 facilitate the respective gas being flowed into mixing chamber 410. Multiple gases can be flowed through gas inlets 413 to mixing chamber 410 to facilitate mixing of such gases.

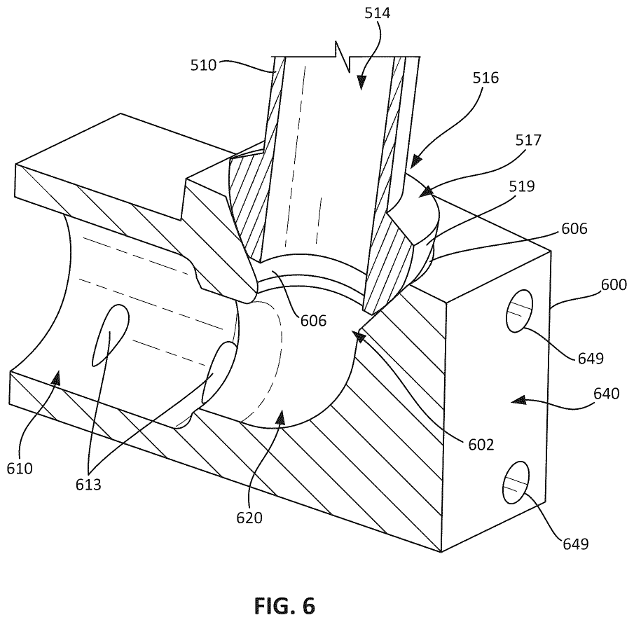

Mixer 400 can comprise a mixer outlet surface 430. Mixer outlet surface 430 can at least partially define an outlet of mixing chamber 410 through which gases can flow into diffuser 130. Mixer 400 can be coupled to diffuser 130 by mixer outlet surface 430 being disposed proximate or adjacent to diffuser inlet surface 135 of diffuser 130. Mixer outlet surface 430 can comprise one or more coupling apertures 439 disposed therein configured to receive a fastener thereto. Coupling apertures 439 of mixer 400 can be disposed in an arrangement or pattern complementary to an arrangement or pattern of coupling apertures 139 of diffuser 130, such that fasteners can be disposed through a mixer distal surface (e.g., distal surface 640 of mixer 600 shown in FIG. 6) and coupling apertures 439 and into coupling apertures 139 of diffuser 130 to coupling mixer 400 and diffuser 130.

In various examples, a reactor system can comprise an activated species supply system, which can fluidly couple the mixer of a reactor and an RPU. For example, reactor system 200 can comprise activated species supply system 300 coupled between RPU 270 and mixer 400. Activated species supply system 300 can comprise an activated species supply conduit 305 spanning therethrough (e.g., through multiple components of activated species supply system 300), through which activated species can flow, and which fluidly couples RPU 270 and mixer 400. Activated species supply system 300 can be disposed upstream of mixer 400 and downstream of RPU 270.

Activated species supply system 300 can comprise a supply tube 310. Supply tube 310 can comprise a supply tube wall 312 at least partially defining a supply tube channel 314. Activated species supply conduit 305 can comprise supply tube channel 314, and activated species from RPU 270 can flow through supply tube channel 314. Supply tube 310 can comprise and span between a supply tube proximal end 316 and a supply tube distal end 318. Supply tube proximal end 316 can be disposed proximate and/or adjacent to, against, and/or coupled to, mixer 400. At least a partial seal can be formed between supply tube proximal end 316 and mixer 400. An O-ring can be disposed between supply tube proximal end 316 and mixer 400 to create the seal, or a seal can be formed via tight fit (e.g., without an O-ring). The at least partial seal can be formed by the material of supply tube 310 contacting the material of mixer 400 (e.g., metal-to-metal contact).

In various examples, the supply tube proximal end can comprise a coupling protrusion extending radially outward from the supply tube wall. The coupling protrusion of the supply tube can be configured to facilitate coupling of the supply tube to the mixer. For example, as depicted in FIGS. 2B, 3, and 4 supply tube proximal end 316 can comprise coupling protrusion 317 extending radially from supply tube wall 312. Coupling protrusion 317 can be configured to couple to, or form at least a partial seal with, mixer 400. In various examples, coupling protrusion 317 can be coupled to mixer 400 via a fastener 449 (i.e., coupling protrusion 317 can be fastened to mixer 400). In various examples, coupling protrusion 317 can be disposed and/or pressed against mixer 400 (e.g., against an inlet surface 406 of mixer 400).

Coupling protrusion 317 can be a coupling flange having a coupling flange shape. Mixer 400 can comprise a coupling recess 404 disposed into mixer inlet surface 406. Coupling recess 404 can have a shape that is complementary to the coupling flange shape of coupling protrusion 317 such that at least a portion of the coupling flange is disposed within coupling recess 404. In response to coupling protrusion 317 being disposed in coupling recess 404, a top surface of coupling protrusion 317 may be flush with mixer inlet surface 406. Coupling protrusion 317 can have chamfered or tapered (i.e., rounded or angled) corners 319. Chamfered corners 319 can facilitate insertion of coupling protrusion 317 into coupling recess 404 to achieve desired alignment and/or positioning.

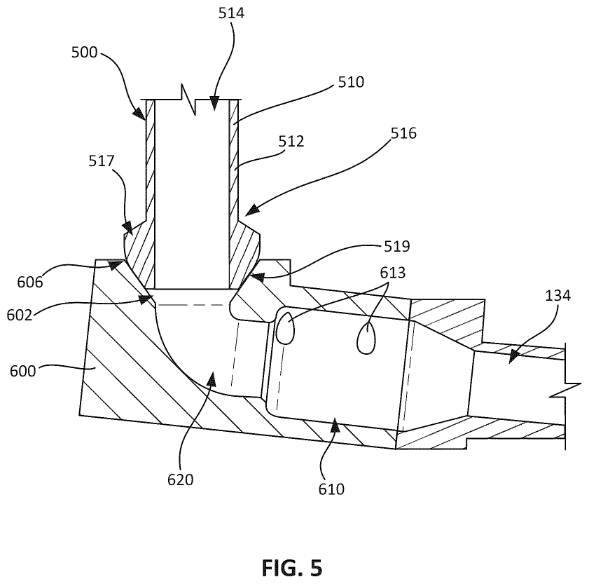

With reference to FIGS. 5 and 6, mixer 600 is another example of a mixer for use in a reactor. Mixer 600 can be, and have components, similar to mixer 400, thus, the description of mixer 400 and its components can apply to mixer 600 and its components. Mixer 600 can comprise a mixing chamber 610, a mixer fluid channel 620, a mixer inlet 602, and gas inlets 613. Supply tube 510 can be, and have components, similar to supply tube 310, thus, the description of supply tube 310 and its components can apply to supply tube 510 and its components. Supply tube 510 can comprise a supply tube wall 512 at least partially defining a supply tube channel 514, and span between a supply tube proximal end 516 and a supply tube distal end. Supply tube proximal end 516 can comprise a coupling protrusion 517 having a tapering surface 519 (e.g., a curved or ball surface). Tapering surface 519 can taper radially inward toward supply tube proximal end 516 (i.e., the radius of tapering surface 519 is smaller closer to supply tube proximal end 516, forming frusto-conical shape). Mixer 600 can comprise mixer inlet 602, which can comprise a tapering coupling recess 606. Tapering coupling recess 606 can be complementary (e.g., in shape, length, angle, etc.) to tapering surface 519 of coupling protrusion 517, such that at least a portion of coupling protrusion 517 is disposed within the tapering coupling recess 606, and/or such that tapering surface 519 and tapering coupling recess 606 align with and/or abut one another to form at least a partial seal therebetween. An O-ring can be disposed between tapering surface 519 and tapering coupling recess 606 to create the seal, or seal can be formed via tight fit (e.g., without an O-ring). Tapering surface 519 and/or tapering coupling recess 606 can accommodate contact and/or coupling between supply tube proximal end 516 and mixer 600 from various angles (e.g., whether supply tube 500 is aligned with mixer fluid channel 620 and/or mixer inlet 602, or at an angle therefrom). That is, tapering surface 519 and/or tapering coupling recess 606 can facilitate contact and/or coupling between supply tube proximal end 516 and mixer 600 even if supply tube 500 is angled (e.g., approaching mixer 600 from an angle other than a desired angle).

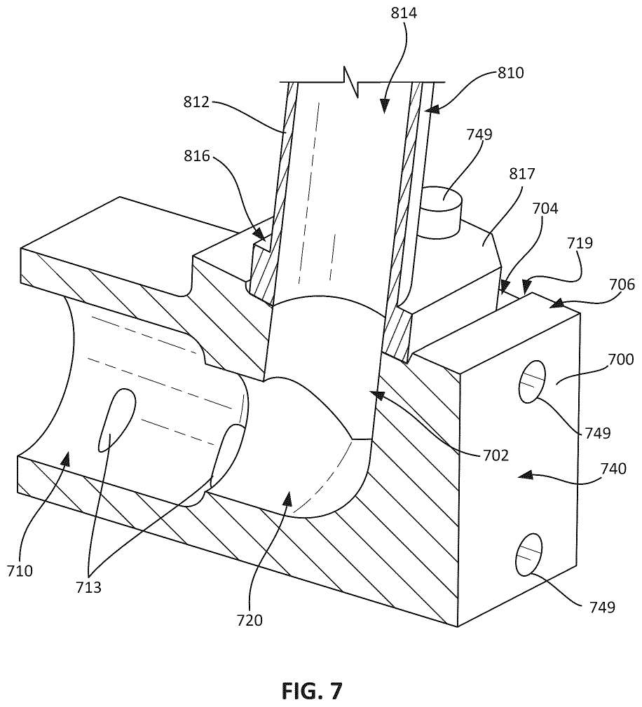

With reference to FIG. 7, mixer 700 is another example of a mixer for use in a reactor. Mixer 700 can be, and have components, similar to mixers 400 and 600, thus, the description of mixers 400 and 600 and their components can apply to mixer 700 and its components. Mixer 700 can comprise a mixing chamber 710, a mixer fluid channel 720, a mixer inlet 702, and gas inlets 713. Supply tube 810 can be, and have components, similar to supply tubes 310 and 510, thus, the description of supply tubes 310 and 510 and their components can apply to supply tube 810 and its components. Supply tube 810 can comprise a supply tube wall 812 at least partially defining a supply tube channel 814, and span between a supply tube proximal end 816 and a supply tube distal end. Supply tube proximal end 816 can comprise a coupling protrusion 817. Coupling protrusion 817 can extend radially from supply tube wall 812. Coupling protrusion 817 can be configured to couple to, or form at least a partial seal with, mixer 700.

In various examples, coupling protrusion 817 can be coupled to mixer 700 via a fastener 749 (i.e., coupling protrusion 817 can be fastened to mixer 700). In various examples, coupling protrusion 817 can be disposed and/or pressed against mixer 700 (e.g., against an inlet surface of mixer 700) without fastener(s).

Coupling protrusion 817 can be a coupling flange having a coupling flange shape. The coupling flange can have a dimension in a first direction that is larger than a direction in a second direction. For example, the dimension of coupling protrusion 817 in a first direction can be larger than in a second direction (e.g., perpendicular from the first direction) to allow space for a coupling aperture and receipt of fastener 749 therein.

Mixer 700 can comprise a coupling recess 704 disposed into mixer inlet surface 706. Coupling recess 704 can have a shape that is complementary to the coupling flange shape of coupling protrusion 817 such that at least a portion of the coupling flange is disposed within coupling recess 704. Coupling recess 704 can have chamfered or tapered (i.e., rounded or angled) sides 719. Chamfered side surfaces can facilitate insertion of coupling protrusion 817 into coupling recess 704 to achieve desired alignment and/or positioning. There can be a seal disposed between supply tube proximal end 816 and mixer 700 to create a seal, or a seal can be formed via tight fit (e.g., without an O-ring and/or fastener(s)).

With reference back to FIGS. 2A, 2B, and 4, reactor 250 can comprise a reactor lid 253. Reactor lid 253 can be coupled to other components of reactor 250 (e.g., a reactor wall system) via fastener 203. Reactor lid 253 can enclose the internal components of reactor 250. A supply aperture 255 can be disposed through reactor lid 253 to allow a portion of activated species supply system 300 to be disposed therein and therethrough. For example, supply tube 310 can be disposed through reactor lid 253 to fluidly couple RPU 270 with internal components of reactor 250 (e.g., mixer 400 and/or diffuser 130).

In various examples, with additional reference to FIGS. 2C and 2D, reactor 250 can comprise a reactor collar 260 coupled to reactor lid 253. Reactor collar 260 can be an intermediate flange to facilitate coupling of various other components of the reactor system. Reactor collar 260 can be coupled to reactor lid 253 via fastener 203 and/or a fastener passing through apertures 269 and into complementary coupling aperture 259 in reactor lid 253. Reactor collar 260 can comprise a collar supply aperture 265 aligned and/or in fluid communication with supply aperture 255 of reactor lid 253. Thus, an activated species can flow through reactor collar 260 via collar supply aperture 265 and reactor lid 253 via supply aperture 255 (e.g., within supply tube 310). A seal 282 can be disposed in collar supply aperture 265 (e.g., an o-ring seal) configured to contact supply tube 310 around its circumference or outer surface and create a seal (or at least a partial seal). Seal 282 can be configured to facilitate alignment of supply tube 310 within collar supply aperture 265 and/or form a seal to prevent or mitigate leaking of an activated species from RPU 270.

In various examples, activated species supply system 300 can comprise a connector tube 320. Connector tube 320 can comprise a connector tube wall 322 at least partially defining a connector tube channel 324. Activated species supply conduit 305 can comprise connector tube channel 324, and activated species from RPU 270 can flow through connector tube channel 324. Connector tube 320 can comprise and span between a connector tube proximal end 326 and a connector tube distal end 328. Connector tube proximal end 326 can be disposed proximate and/or adjacent to, against, and/or coupled to, RPU 270. At least a partial seal can be formed between connector tube proximal end 326 and RPU 270. Connector tube distal end 328 can be disposed proximate and/or adjacent to, against, and/or coupled to, supply tube distal end 318. At least a partial seal can be formed between connector tube distal end 328 and supply tube distal end 318. An O-ring can be disposed between connector tube distal end 328 and supply tube distal end 318 to create the seal, or seal can be formed via tight fit (e.g., without an O-ring). The at least partial seal can be formed by the material of connector tube 320 contacting the material of supply tube 310 (e.g., metal-to-metal contact).

Connector tube 320 can comprise any suitable shape or configuration. Based on the arrangement of RPU 270 relative to reactor 250, connector tube 320 can be angled or curved to connect and fluidly couple the outlet 272 of RPU 270 with supply aperture 255 in reactor lid 253 and/or supply tube distal end 318 of supply tube 310. Connector tube 320 can span along a different axis than supply tube 310. In various examples, connector tube 320 can comprise a straight-line shape between RPU 270 and supply tube distal end 318 of supply tube 310.

Activated species supply system 300 can comprise a connector flange 330. Connector flange 330 can be coupled to connector tube distal end 328. Connector flange 330 can extend radially outward from connector tube wall 322 (i.e., connector flange 330 can have a radius and/or other similar dimension that is larger than the corresponding dimension of connector tube 320). Connector flange 330 can be a separate component from connector tube 320 coupled to connector tube distal end 328, or connector flange 330 can be a monolithic component of connector tube wall 322. Connector flange 330 can be disposed against reactor lid 253 (or a recess 257 within reactor lid 253 having a complementary shape to that of connector flange 330). Connector flange 330 can facilitate the coupling and/or engagement between supply tube 310 and connector tube 320. Connector flange 330 can be coupled to reactor lid 253 in any suitable manner, e.g., via a fastener 339 (such as a screw, bolt, name, and/or the like), an adhesive, tight fit, magnet, and/or the like) passing through connector flange 330 and into a complementary coupling aperture 259 in reactor lid 253.

Supply tube 310 can comprise a supply tube flange 313 protruding radially outward from supply tube wall 312. Supply tube flange 313 can be disposed between supply tube proximal end 316 and supply tube distal end 318 (e.g., more proximate supply tube distal end 318). Activated species supply system 300 can comprise a spring 309 (e.g., a compression spring, a wave spring, and/or the like) coupled to and/or disposed about supply tube 310. Spring 309 can have a first end that is coupled to, engaged with, and/or applies force against supply tube flange 313 (e.g., on a surface of supply tube flange 313 that is facing upward and/or in an upstream direction). Spring 309 can have a second end opposite the first end configured to couple to, engage with, and/or apply force against connector flange 330 (i.e., the second end of spring 309 can be disposed against connector flange 330), as shown in FIG. 2B. In response to connector flange 330 being coupled to reactor lid 253, spring 309 may span, and be compressed between, supply tube flange 313 and connector flange 330. As depicted in FIG. 2C, the second end of spring 309 can be configured to couple to, engage with, and/or apply force against reactor collar 260. Reactor collar 260 can compress spring 309 and be coupled to reactor lid 253, thus holding spring 309 and supply tube 310 in place. Such coupling can occur before coupling of connector flange 330 and/or connector tube 320 with reactor 250, so connector flange 330 and connector tube 320 can be coupled with reactor 250 without resistance and/or movement from spring 309, supply tube 310, or other proximate components. In response to reactor collar 260 being coupled to reactor lid 253, spring 309 may span, and be compressed between, supply tube flange 313 and reactor collar 260.

Spring 309 can have a bias toward an extended position, and thus, when compressed between supply tube flange 313 and connector flange 330 and/or reactor collar 260, spring 309 can apply a force on connector flange 330 and/or reactor collar 260 (e.g., in an upstream direction) and on supply tube flange 313 (e.g., in a downward and/or downstream direction toward mixer 400). The force on supply tube flange 313 from spring 309 can cause greater contact between supply tube proximal end 316 and mixer 400 (e.g., at the coupling recess of the mixer). For example, with additional reference to FIGS. 5 and 6, the spring in the activated species supply system 300 can press supply tube 510 against mixer 600 (e.g., press supply tube proximal end 316 with tapering surface 519 into tapering coupling recess 606) to create greater contact therebetween relative to the absence of spring force. This can facilitate the at least partial seal formed between the supply tube and the mixer discussed herein (e.g., with or without coupling via fastener(s)).

The components of a reactor system, including a reactor, activated species supply system, mixer, etc., can comprise any suitable material. For example, the mixer can comprise titanium metal, a titanium alloy, and/or a steel alloy (e.g., stainless steel). Components of the activated species supply system can comprise a steel alloy (e.g., stainless steel). In various examples, the mixer, supply tube, and/or the connector tube can comprise a coating (e.g., along the activated species supply conduit 305, for example coating 311 in FIG. 3) comprising aluminum oxide. Such a coating can mitigate or prevent radical recombination, thus prolonging the life of activated species flowing from RPU 270 to diffuser 130 so a greater amount of activated species is available for desired processing in the reactor.

The examples described herein do not limit the scope of the disclosure, since these examples are merely exemplary embodiments of the disclosure, which is defined by the appended claims and their legal equivalents. Any equivalent examples are intended to be within the scope of this disclosure. Indeed, various modifications of the disclosure, in addition to those shown and described herein, such as alternative useful combinations of the elements described, may become apparent to those skilled in the art from the description. Such modifications and examples are also intended to fall within the scope of the appended claims.

1. A reactor system, comprising:
a remote plasma unit;
a reactor coupled to the remote plasma unit, the reactor comprising:
a reaction chamber;
a diffuser in fluid communication with the reaction chamber; and
a mixer coupled to, and in fluid communication with, the diffuser, wherein the mixer comprises a mixing chamber and a mixer fluid channel fluidly coupled to, and upstream of, the mixing chamber; and
an activated species supply system fluidly coupled to the mixer upstream of the mixer fluid channel, wherein the activated species supply system comprises an activated species supply conduit that fluidly couples the remote plasma unit with the mixer.

2. The reactor system of claim 1, wherein the reactor further comprises a reactor lid, wherein the reactor lid comprises a supply aperture,
wherein the activated species supply system further comprises a supply tube comprising a supply tube wall defining a supply tube channel and spanning between a supply tube proximal end and a supply tube distal end, wherein the activated species supply conduit comprises the supply tube channel, wherein the supply tube is disposed through the supply aperture in the reactor lid, and wherein the supply tube proximal end is positioned against the mixer such that the supply tube channel is in fluid communication with the mixer fluid channel.

3. The reactor system of claim 2, wherein the activated species supply system further comprises a connector tube comprising a connector tube wall defining a connector tube channel and spanning between a connector tube proximal end and a connector tube distal end, wherein the activated species supply conduit comprises the connector tube channel, wherein the connector tube distal end is coupled to the supply tube distal end such that the supply tube channel is in fluid communication with the connector tube channel, and wherein the connector tube proximal end is coupled to the remote plasma unit.

4. The reactor system of claim 3, wherein the activated species supply system further comprises a connector flange coupled to the connector tube distal end, wherein the connector flange extends radially outward from the connector tube wall and is coupled to the reactor lid.

5. The reactor system of claim 4, wherein the connector flange is one of:
a separate component coupled to the connector tube distal end, or
a monolithic component of the connector tube wall.

6. The reactor system of claim 4, wherein the supply tube comprises a supply tube flange protruding radially outward from the supply tube wall at a flange position between the supply tube proximal end and the supply tube distal end,
wherein the activated species supply system further comprises a spring disposed about the supply tube having a spring first end applying force against the supply tube flange and a spring second end applying force against at least one of the connector flange, the reactor lid, or a reactor collar disposed between the connector flange and the reactor lid.

7. The reactor system of claim 6, wherein in response to the connector flange or the reactor collar being coupled to the reactor lid, the spring applies force on the supply tube flange causing greater contact between the supply tube proximal end and the mixer.

8. The reactor system of claim 2, wherein the supply tube proximal end comprises a coupling protrusion extending radially outward from the supply tube wall and configured to couple to the mixer.

9. The reactor system of claim 8, wherein coupling protrusion is fastened to the mixer.

10. The reactor system of claim 8, wherein the coupling protrusion comprises a coupling flange with a flange shape, wherein the mixer comprises a coupling recess at an inlet of the mixer fluid channel, wherein the coupling recess comprises a shape that is complementary to the flange shape such that at least a portion of the coupling flange is disposed within the coupling recess.

11. The reactor system of claim 8, wherein the coupling protrusion comprises a tapering surface that tapers radially inward toward the supply tube proximal end, wherein the mixer comprises a tapering coupling recess at an inlet of the mixer fluid channel, wherein the tapering coupling recess is complementary to the tapering surface of the coupling protrusion, such that at least a portion of the coupling protrusion is disposed within the tapering coupling recess.

12. The reactor system of claim 1, further comprising a gas source,
wherein the mixing chamber further comprises a gas inlet, wherein the gas source is fluidly coupled to the mixing chamber via the gas inlet.

13. The reactor system of claim 3, where in the mixer comprises at least one of titanium metal or a titanium alloy, and wherein the supply tube and the connector tube comprise stainless steel.

14. The reactor system of claim 13, wherein an inside surface of at least one of the mixer, the supply tube, or the connector tube comprises a coating comprising aluminum oxide.

15. The reactor system of claim 2, wherein at least a partial seal is formed between the supply tube proximal end and the mixer via tight fit.

16. A reactor system, comprising:
a mixer, comprising:
a mixing chamber;
a mixer fluid channel fluidly coupled to, and upstream of, the mixing chamber; and
a mixer fluid channel inlet comprising a coupling recess,
wherein the mixer is a monolithic component including the mixing chamber and the mixer fluid channel; and
a supply tube comprising a supply tube wall defining a supply tube channel and spanning between a supply tube proximal end and a supply tube distal end, wherein the supply tube proximal end is disposed at least partially within the coupling recess of the mixer fluid channel inlet.

17. The reactor system of claim 16, wherein the mixer fluid channel is an elbow joint between the supply tube and the mixing chamber, and wherein the supply tube proximal end comprises a coupling protrusion extending radially outward from the supply tube wall, wherein the coupling protrusion comprises a shape that is complementary to a shape of the coupling recess.

18. A reactor system, comprising:
a remote plasma unit;
a reactor coupled to the remote plasma unit, the reactor comprising a mixer; and
an activated species supply system fluidly coupled between the remote plasma unit and the mixer, the activated species supply system comprising a supply tube coupled to the mixer, wherein the activated species supply system is disposed through a reactor lid.

19. The reactor system of claim 18, wherein the activated species supply system further comprises a spring disposed about the supply tube and applying a force on the supply tube to cause greater contact between the supply tube and the mixer.

20. The reactor system of claim 18, wherein the activated species supply system further comprises a connector tube fluidly coupled between the supply tube and the remote plasma unit, wherein the supply tube spans along a different axis than the connector tube.
